(19) United States
(12) Patent Application Publication
(10) Pub. No.: US 2007/0223194 A1
(43) Pub. Date: Sep. 27, 2007

(54) Cooling assembly for an electrical appliance and method for liquid cooling

(75) Inventor: Karsten Laing, Althuette (DE)

Correspondence Address: Lipsitz & McAllister, LLC, 755 MAIN STREET, MONROE, CT, 06468, US

(73) Assignees: Karsten Laing, Althuette (DE); Oliver Laing, Stuttgart (DE); Birger Laing, Marbach (DE)

(21) Appl. No.: 11/710,621

(22) Filed: Feb. 23, 2007

Related U.S. Application Data
(63) Continuation of application No. PCT/EP05/08917, filed on Aug. 17, 2005.

(30) Foreign Application Priority Data
Aug. 26, 2004 (DE) 10 2004 042 034.3
Sep. 3, 2004 (DE) 10 2004 043 398.4

(51) Int. Cl. H05K 7/20

(52) U.S. Cl. 361/699

(57) ABSTRACT

A cooling assembly for an electrical appliance with one or several heat sources is provided, wherein the electrical appliance has an electrical power supply unit with at least one heat source; the cooling assembly comprises a fan device for cooling the at least one heat source of the power supply unit by means of a stream of air and a liquid cooling device. The fan device is arranged such that a radiator of the liquid cooling device can be acted upon at least partially by a steam of air from the fan device.

This application is a continuation of International application No. PCT/EP2005/008917 filed on Aug. 17, 2005.

The present disclosure relates to the subject matter disclosed in International application No. PCT/EP2005/008917 of Aug. 17, 2005 and German applications No. 10 2004 042 034.3 of Aug. 26, 2004 and No. 10 2004 043 398.4 of Sep. 3, 2004, which are incorporated herein by reference in their entirety and for all purposes.

### BACKGROUND OF THE INVENTION

The invention relates to a cooling assembly (cooling arrangement) for an electrical appliance with one or several heat sources, wherein the electrical appliance has an electrical power supply unit with at least one heat source, comprising a fan device for cooling the at least one heat source of the power supply unit by means of a stream of air and a liquid cooling device.

The invention relates, in addition, to a method for the liquid cooling of at least one heat source of an electrical appliance, with which a stream of air from a fan device acts on a radiator.

Liquid cooling devices are described, for example, in EP 1 398 511 A1 and US 2004/011937 A1, respectively, or in WO 03/098415 A1.

### SUMMARY OF THE INVENTION

In accordance with the present invention, a cooling assembly is provided which can be used in a space-saving manner.

In accordance with an embodiment of the invention, the fan device is arranged such that a radiator of the liquid cooling device can be acted upon at least partially with a stream of air from the fan device.

In the radiator of a liquid cooling device, an exchange of heat with the surroundings is provided for, in particular, via an increase in the surface area of the flow guidance in order to be able to cool heated cooling liquid again. Normally, a fan is associated with a radiator in order to be able to act on the radiator with a stream of air. In the case of the solution in accordance with the invention, the fan device provides for a cooling of the power supply unit and of the radiator. The number of structural components may be kept small as a result. In particular, only one single fan device need be provided. A fan of the fan device can be of a larger design so that the noise made by the fan can also be minimized per fan.

It is possible, for example, to design the power supply unit so as to be fan-free. As a result, the power supply unit can be designed with smaller space requirements. The space which will then be free in relation to a given housing of the electrical appliance can be used for the purpose of positioning the liquid cooling device with the fan device (which also provides for cooling of the radiator). The cooling assembly can therefore be arranged in a space-saving manner, for example, in a housing of an electrical appliance.

In principle, it is also possible for the radiator to be integrated into the power supply unit.

It is particularly advantageous when the fan device and the radiator are arranged in relation to the power supply unit such that the at least one heat source of the power supply unit and the radiator can be cooled via the fan device. A stream of air from the fan device then provides for an air cooling of the power supply unit and for an air cooling of the cooling liquid in the radiator. As a result, a space-saving design of the cooling assembly is obtained with an effective cooling not only of the power supply unit but also of the cooling liquid.

For example, the power supply unit may be designed to be fan-free. The power supply unit then needs less space in comparison with power supply units with an integrated fan. As a result, space is again made available, for example, in a housing of an electrical appliance which can be utilized for the positioning of the radiator and, therefore, can be utilized at least for the positioning of components of the liquid cooling device.

The fan device is arranged, in particular, in a space next to the power supply unit. As a result, it may be ensured that the stream of air from the fan device reaches the power supply unit in order to be able to bring about the air cooling. In addition, the space made available, for example, as a result of the decrease in size of the power supply unit is then used effectively.

The radiator is also favorably arranged in a space next to the power supply unit.

It may be provided for the power supply unit and the fan device to be arranged on a common support. As a result, the power supply unit and the fan device can be mounted in a simple manner, for example, in a housing of an electrical appliance.

For the same reason it is favorable when the power supply unit and the radiator are arranged on a common support or the fan device and the radiator are arranged on a common support.

It is, in addition, favorable when a circulation pump of the liquid cooling device and the power supply unit are arranged on a common support. As a result, the cooling assembly may be mounted in a simple manner.

It is, in principle, also possible for the radiator to be integrated into the power supply unit. The fan device, in particular, is then also integrated into the power supply unit. As a result, a cooling-power supply module may be made available which can be mounted in a simple manner.

It is particularly advantageous when a circulation pump for the liquid cooling is provided and, in particular, integrated into the power supply unit. As a result, a module can be made available which contains the necessary components for the liquid cooling; as a result, the liquid cooling device may be mounted on the electrical appliance and also used in a simple manner.

It may be provided for the circulation pump to be arranged on a housing of the power supply unit. A power supply-liquid cooling module may then be made available, wherein the circulation pump is already in position. The housing of the power supply unit provides a suitable location for mounting the circulation pump.

The circulation pump is arranged, in particular, outside a housing interior of a housing of the power supply unit. The circulation pump may then be positioned and mounted in a simple manner with respect to the power supply unit. The power supply unit may be designed so as to save on space. When maintenance work has to be carried out on the circulation pump or the circulation pump has to be exchanged, this may be carried out in a simple manner.

It is particularly advantageous when the circulation pump is connected to at least one thermal contact element. The thermal contact element, which is connected to the circulation pump, in particular, via flexible hose-like liquid conduits, can then be fixed to one or more relevant objects of the electrical appliance in thermal contact. For example, it may be positioned on the CPU of a computer and a graphics processor in order to provide for their cooling.

At least one thermal contact element is, in particular, connected to the circulation pump via liquid lines in such a manner that an object can be contacted thermally by the at least one thermal contact element. Liquid conduits, at which the (at least one) thermal contact element is arranged, are guided out of the power supply unit with integrated circulation pump. The power supply unit is mounted, for example, in the housing of the electrical appliance. The thermal contact element is then positioned on the object, such as a CPU or a graphics processor, and fixed in place. The overall assembly is considerably simplified since the individual components of the liquid cooling device need not be mounted separately in the housing of the electrical appliance.

There are, in principle, two possibilities for arranging the circulation pump and the radiator relative to one another in a flow guidance. With respect to the direction of flow of heated cooling liquid, i.e., in the direction of flow of cooling liquid which flows away from a thermal contact element, the radiator may be arranged upstream of the circulation pump or downstream of the circulation pump. It is favorable when the circulation pump is arranged upstream of the radiator in the flow guidance for cooling liquid with respect to a direction of flow for heated cooling liquid, i.e., the circulation pump follows the thermal contact element. The circulation pump then has heated cooling liquid flowing through it which is subsequently cooled in the radiator. Cooled cooling liquid is then supplied from the radiator directly to a thermal contact element. Such a flow guidance is favorable from an energy point of view.

It is provided, in particular, for the circulation pump to be arranged at or in the vicinity of a feed-through for a loom of cables. A loom of cables must be guided via a passage through a housing of a power supply unit. The loom of cables contains the cables, via which internal electrical consumer devices of the electrical appliance are supplied with current. The loom of cables exiting from the power supply unit requires space. For this reason, a specific space must be kept free for the loom of cables behind the power supply unit. When the circulation pump (and, where applicable, also a compensation reservoir) are arranged at or in the vicinity of the passage, this space, which has to be kept free in any case, can then be utilized effectively. The actual spatial requirements of the cooling assembly may be kept small as a result.

The circulation pump is arranged, in particular, on a supporting plate which is located opposite an electrical connection. Electrical power is coupled into the power supply unit from outside via the electrical connection. Normally, the electrical connection is a mains power connection. A passage for a loom of cables is normally arranged at the supporting plate. Space must be kept free in any case behind the loom of cables in order to be able to guide this to the outside. When the circulation pump is arranged on the supporting plate, this space in a housing of an electrical appliance can then be utilized for accommodating the circulation pump.

It is particularly advantageous when the radiator and the fan device are arranged one behind the other, wherein the radiator can be arranged in front of or behind the fan device with respect to a suction side. It is ensured by the arrangement of radiator and fan device one behind the other that the radiator can be cooled via the stream of air from the fan device.

It is particularly favorable when the radiator is arranged beneath an electrical connection of the power supply unit. As a result, a circulation of air through an interior space of the power supply unit can be ensured. Normally, openings and, in particular, ventilation slits of a power supply unit are arranged next to the electrical connection. When the radiator is located beneath the electrical connection, such ventilation slits are not covered completely.

It may be provided for an axis of rotation of the fan device to be oriented transversely to an axis of rotation of the circulation pump. As a result, a space-saving integration of the liquid cooling device into the power supply unit may be realized.

It is favorable when the circulation pump has an electric motor with a spherically mounted rotor. Such circulation pumps are described in EP 1 416 607 A2 and US 2004/0119371 A1, respectively, and in EP 1 398 511 A1 and US 2004/0052663 A1, respectively, to which reference is expressly made. Such electric motors and, therefore, the circulation pumps, into which such electric motors are integrated, may be designed with a low height. Furthermore, the corresponding electric motors are particularly silent during running and so the noise emission is reduced. Furthermore, corresponding electric motors have a long service life.

An impeller of the circulation pump is connected, in particular, to the rotor which drives the impeller accordingly.

It is favorable when at least one compensation reservoir for cooling liquid is provided. As a result, it is possible to fill the liquid cooling device with a greater amount of cooling liquid than is necessary for actual operation. As a result, a normal reduction in cooling liquid, for example, due to diffusion and evaporation can be compensated for and so with sufficient prefilling any subsequent filling during the service life of the liquid cooling device is not necessary.

The at least one compensation reservoir is, in particular, integrated into the power supply unit. As a result, an overall system is provided which includes the necessary components for the liquid cooling.

It may also be provided for the at least one compensation reservoir to be integrated into the circulation pump, i.e., to be arranged, in particular, within a housing of the circulation pump.

The cooling assembly comprises, in particular, the components radiator, circulation pump, expansion reservoir and the fan device.

It is favorable, in addition, when exiting liquid lines are present, at which at least one thermal contact element is arranged. The liquid lines are, in particular, of a flexible design as hoses. One or more thermal contact elements can then be positioned in relation to one or more objects to be cooled.

It is particularly advantageous when the liquid cooling device is prefilled with such an amount of cooling liquid that no subsequent filling is necessary during an expected service line. The liquid cooling device contains as a prefabricated system such an amount of cooling liquid (for example, a water-antifreeze mixture) that losses of cooling liquid, for example, due to diffusion and evaporation can be compensated for.

In accordance with the present invention, a method is provided by means of which an effective cooling can be achieved.

In accordance with an embodiment of the present invention, a stream of air from the fan device also acts on a power supply unit of the electrical appliance such that one or more heat sources of the power supply unit are cooled by means of the stream of air.

The method in accordance with the invention has the advantages already explained in conjunction with the cooling assembly according to the invention.

Additional advantageous developments have likewise already been explained in conjunction with the cooling assembly according to the invention.

The following description of a preferred embodiment serves to explain the invention in greater detail in conjunction with the drawings.

### BRIEF DESCRIPTION OF THE DRAWINGS

FIG. 1 shows a side sectional view of one embodiment of a cooling assembly according to the invention;

FIG. 2 shows a view of the cooling assembly according to FIG. 1 in the direction A without a fan device;

FIG. 3 shows the same view as in FIG. 2 with a fan device (without liquid conduits);

FIG. 4 shows a view of the cooling assembly according to FIG. 1 in the direction B and

FIG. 5 shows a view of the cooling assembly according to FIG. 1 in the direction C (opposite direction to direction B).

### DETAILED DESCRIPTION OF THE INVENTION

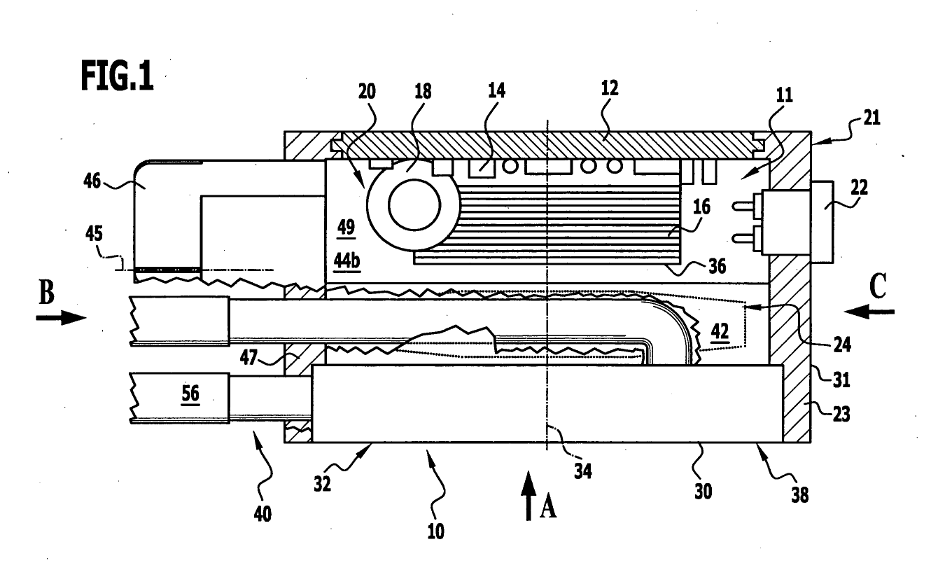

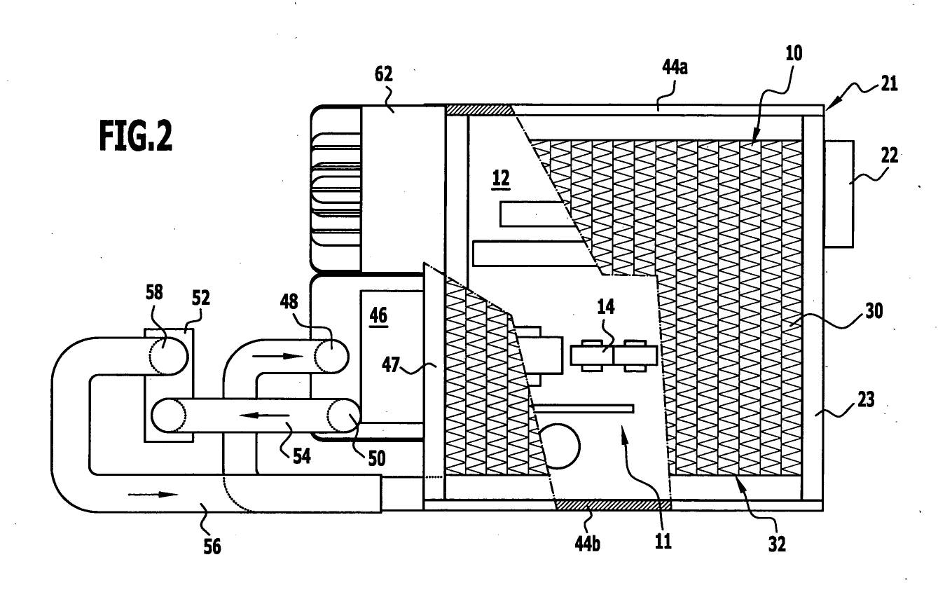

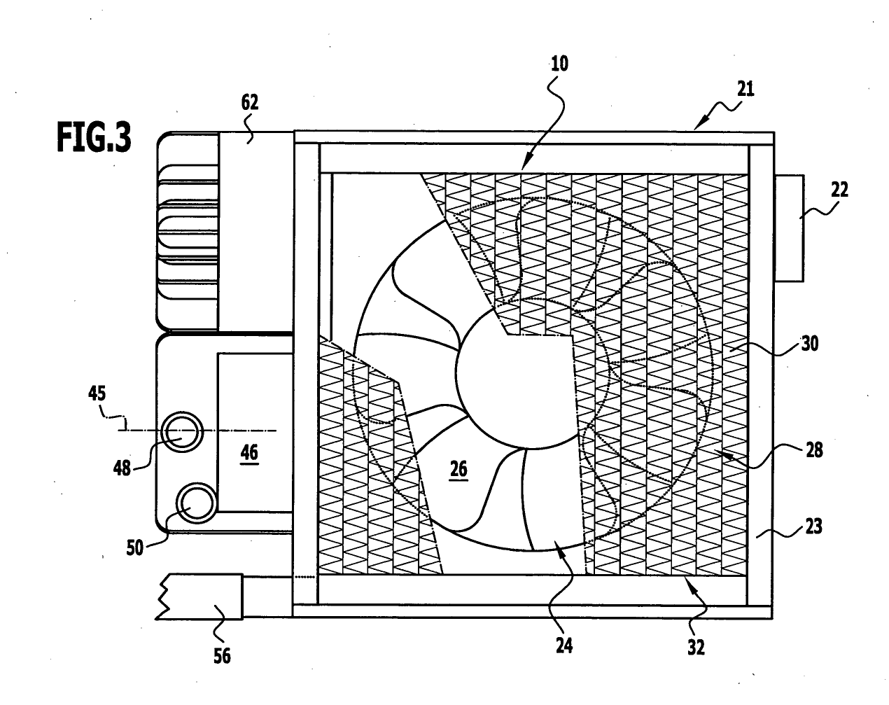

One embodiment of a cooling assembly in accordance with the invention is shown in FIGS. 1 to 5 and designated as 10. It serves the purpose of cooling an electrical appliance (electrical device). Heat sources of the electrical appliance, in particular, are cooled. The cooling assembly 10 is positioned, for example, in a housing of the electrical appliance.

The electrical appliance comprises a power supply unit 11 for making electrical power available at internal electrical consumer devices of the electrical appliance in the suitable form.

The power supply unit 11 comprises, for example, a support 12 for functional components 14 of the power supply unit 11. Electronic components are arranged, in particular, on the support 12 as functional components 14. A cooling member 16 can also be arranged on the support 12. This cooling member 16 which has a plurality of cooling ribs is in thermal contact with one or several electronic power components 18 of a circuit arrangement 20 arranged on the support 12. The cooling member 16 is a secondary heat source, wherein one or several electronic components, which become hot during operation, are corresponding primary heat sources.

The power supply unit 11 has a closed housing 21, in which the circuit arrangement 20 is seated. The housing 21 is, in particular, a steel housing. The housing 21 is designed such that it has a (cooling) stream of air flowing through it.

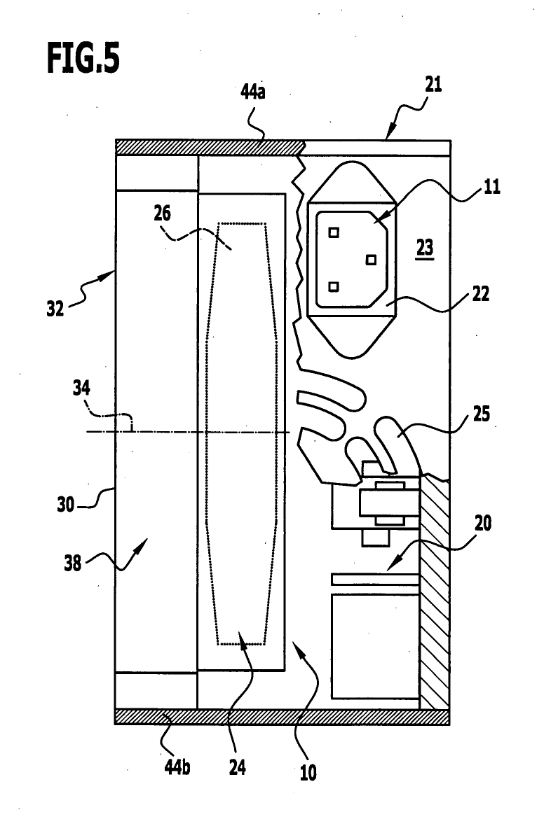

The electrical power supply unit 11 has an electrical connection 22 for the external supply of current which is, in particular, a mains connection. This is arranged on a rear plate 23 of the housing 21. The rear plate 23 is provided with openings 25 (FIG. 5) which are arranged next to the electrical connection 22. Electrical power may be coupled into the power supply unit 11 via the electrical connection 22, wherein the power supply unit 11 provides for a conversion of electricity with its circuit arrangement 20 and so electrical power can be made available to electronic components of an electrical appliance, such as, for example, a computer and, in particular, PC in the required form.

A fan device 24 with a rotatingly driven fan wheel 26 of a fan 28 is associated with the power supply unit 11. A protective guard 30 is arranged in front of the fan wheel 26.

The power supply unit 11 and the fan device 24 may be arranged on a common support 31. The fan device 24 is arranged, in particular, in a space next to the power supply unit 11.

A cooling stream of air can be generated via a suction side 32 which (covered by the protective guard 30) is open at least partially. The suction side 32 is oriented transversely and, in particular, at right angles to the rear plate 23.

The fan 28 is arranged such that the cooling member 16, in particular, can be cooled via the stream of air. The stream of air is also directed, for example, such that it also acts directly, at least partially, on power components 18.

In the embodiment shown, an axis of rotation 34 of the fan wheel 26 is aligned transversely and, in particular, at right angles to a side surface 36 of the cooling member 16. In addition, the axis of rotation 34 is aligned transversely and, in particular, at right angles to the carrier 12 for the circuit arrangement 20. Furthermore, the axis of rotation 34 is oriented, in particular, parallel to the rear plate 23.

With the positioning of the power supply unit 11 in a housing of the corresponding electrical appliance, for the power supply of which it is responsible, the suction side 32 preferably points downwards into the interior of the housing. The housing of the electrical appliance is, in particular, provided with an opening, at which the rear plate 23 of the power supply unit 11 is positioned. This opening is normally located at a rear side of the housing of the electrical appliance.

In accordance with the invention, it is provided for a radiator 38 of a liquid cooling device 40 to be arranged such that it (i.e., the liquid which flows through the radiator 38) can be cooled via the fan device 24.

The radiator 38 is arranged, in particular, such that it can be acted upon at least partially by the stream of air from the fan device 24 in order to provide for cooling.

A circulation of air with the surroundings is facilitated by the openings 25 designed, in particular, as ventilation slits. As a result, any congestion of air in the housing of the electrical appliance is avoided.

The radiator 38 has a cooling section 42, through which (heated) liquid flows. In the cooling section 42, the liquid can be cooled by the fan device 24, in particular, on account of the action of the stream of air.

In the solution according to the invention, a common fan device, namely the fan device 24 for the power supply unit 11 and for the liquid cooling device 40, is provided. The fan wheel 26 can be of a larger design; as a result, the generation of noise by the fan device 24 is reduced.

In order to hold the radiator 38, oppositely located supports 44a, 44b are, for example, provided. The supports 44a, 44b can also hold the fan device 24. They are fixed, for example, to the housing 21.

In the cooling assembly 10, the radiator 38 and the fan device 24 are arranged one behind the other so that the stream of air from the fan device 24 flows past the cooling section 42. In relation to the protective guard 30, the fan device 24 can be arranged in front of or behind the radiator 38. The radiator 38 is preferably arranged so as to be mechanically protected.

It may be provided, for example, for the radiator 38 to “cover” only one section of the flow surface of the fan device 24 so that the stream of air from the fan 28 can act directly on the cooling member 16 via another section.

A circulation pump 46 of the liquid cooling device 40 is positioned in a space next to the power supply unit 11. The circulation pump 46 is, for example, a circulation pump with a spherically mounted rotor, on which an impeller is seated. Such a circulation pump is described, for example, in EP 1 398 511 A1 and US 2004/0052663 A1, respectively, or in EP 1 416 607 A2 and US 2004/0119371 A1, respectively. Reference is expressly made to these publications.

An axis of rotation 45 of the rotor of the circulation pump is located transverse and, in particular, at right angles to the axis of rotation 34 of the fan wheel 26.

It may be provided for the cooling assembly 10 with the fan device 24 and the liquid cooling device 40 to form a cooling module which can be inserted into a housing of the corresponding electrical appliance (for example, a computer). This module can also comprise the power supply unit 11.

The circulation pump 46 is fixed, for example, to a supporting plate 47 of the power supply unit 11 which is located opposite the rear plate 23 and is seated between the supports 44a, 44b. It is arranged, in particular, outside a housing interior 49 of the housing 21.

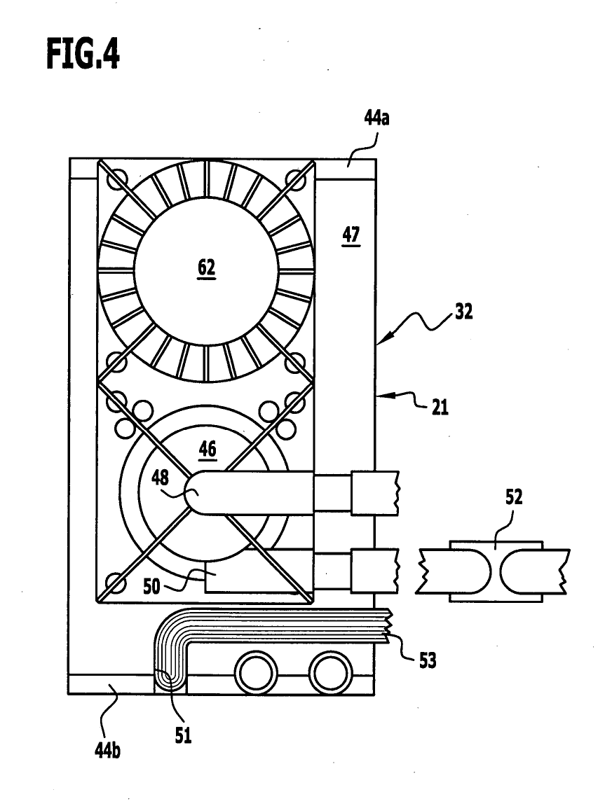

A feed-through 51 for one or several looms of cables 53 is seated on the supporting plate 47 (FIG. 4). Current is supplied to electrical consumer devices of the electrical appliance via this loom of cables 53 (or looms of cables 53, respectively).

The circulation pump 46 is supplied with electrical power via the electrical power supply unit 11. For this purpose, it is connected electrically to corresponding outlet connections of the circuit arrangement 20, for example, by means of cables of the loom of cables 53.

The circulation pump 46 has a first liquid connection 48 and a second liquid connection 50. (At least) one thermal contact element 52 is in effective fluid connection with these two connections 48, 50 and this contact element can be fixed to one or several electronic power components (which are heat sources) of the electrical appliance in order to be able to carry heat away.

For example, it is provided for the thermal contact element 52 to be fixed to the CPU of a computer in thermal contact with it. Alternatively or in addition, it may also be provided for the thermal contact element 52 or an additional thermal contact element to be connected thermally to a graphics processor of a computer.

The thermal contact element 52 serves the purpose of providing the thermal contact to a heat source (heat sink). The thermal contact element 52 has cooling liquid flowing through it to enable it to carry heat away from the thermal contact element 52 and, therefore, from the heat source.

The thermal contact element 52 is connected to the second liquid connection 50 of the circulation pump 46 via a first liquid conduit 54. This is, in particular, a (flexible) hose.

The thermal contact element 52 is connected to the first liquid connection 48 of the circulation pump 46, in addition, via a second liquid conduit 56.

The radiator 38 is arranged between a corresponding connection 58 of the thermal contact element 52 and the first liquid connection 48 of the circulation pump 46; heated cooling liquid which comes from the thermal contact element 52 may be cooled in the radiator 38 with its areal cooling section 42 so that cooled cooling liquid can be supplied to the circulation pump 46 via the liquid connection 48.

It is also possible for the connection 58 of the thermal contact element 52 to be connected to the circulation pump 46 via the connection 48. The connection 50 is then connected to the radiator 38. In the flow guidance of the cooling liquid, the circulation pump 46 is then arranged immediately downstream of the thermal contact element 52 and upstream of the radiator 38. As a result, the circulation pump 46 has heated cooling liquid flowing through it prior to its cooling in the radiator 38.

The circulation pump can also supply several thermal contact elements with cooling liquid or several circulation pumps are provided.

The liquid cooling device 40 comprises a compensation reservoir 62 for cooling liquid. This may be a separate vessel, as shown in the Figures, or the compensation reservoir can be integrated into the circulation pump 46.

The expansion reservoir 62 has, for example, a volume in the order of magnitude of 50 cm³. It is arranged, in particular, on the supporting plate 47 next to the circulation pump 46.

The liquid cooling device 40 is preferably prefilled with the required amount of cooling liquid which is sufficient for the expected customary service life and so no subsequent filling is necessary. The compensation reservoir 62 makes the additional space required for this available for the cooling liquid.

In accordance with the invention, a cooling assembly is made available which is of a simple and space-saving construction. Heat sources of an electrical appliance may be liquid cooled and cooled via a steam of air via the cooling assembly according to the invention. At least one heat source of the power supply unit 11 of the electrical appliance is, in particular, cooled via the fan device 24 which provides at the same time for a cooling of the radiator 38 via a stream of air.

The thermal contact element or elements 52 are then brought into thermal contact with the objects of the electrical appliance to be cooled, in particular, with electronic power components, i.e., are fixed mechanically in position relative to them in such a manner that a good thermal contact is present.

During operation of the power supply unit 11, this makes the necessary electrical power available to the electrical appliance. Furthermore, the circulation pump 46 is driven in order to pump cooling liquid through the thermal contact element or elements 52. As a result, heat may be removed from the corresponding object in contact with a thermal contact element 52. The heated cooling liquid is then fed to the radiator 38, at which it can cool. A stream of air from the fan device 24 acts on the radiator 38 and the circuit arrangement 20 of the power supply unit 11, as well, at least partially. In this respect, the fan device 24 provides at the same time for an air cooling of the heated cooling liquid and for an air cooling of the circuit arrangement 20.

In this respect, it is possible for the radiator 38 to be arranged such that cooled cooling liquid is guided past the circuit arrangement 20 in order to be able to cool this in addition—via cooling liquid.

The fan device 24 is a fan device common to the radiator 38 and the power supply unit 11 and, in particular, its circuit arrangement 20.

The cooling assembly 10 is preferably prefabricated, i.e., all the necessary components of the liquid cooling device 40 are assembled; in particular, the radiator 38, the circulation pump 46, the fan device 24, the liquid conduits 54, 56 and also the thermal contact element or elements 52 are assembled. Furthermore, the system is prefilled with an adequate amount of cooling liquid and so no subsequent filling during the customary expected service life is necessary.

A separate fan device need no longer be provided for the power supply unit 11. As a result, the power supply unit 11 may be of a smaller design than usual. The space thereby obtained may, on the other hand, be used for the positioning of components of a liquid cooling device. In particular, the fan device 24, which also provides for the cooling of cooling liquid in the radiator 38, can then be positioned in a space next to the power supply unit 11. Furthermore, the circulation pump 46 can be positioned next to the power supply unit 11. The radiator 38 can also be positioned next to the power supply unit 11.

1. Cooling assembly for an electrical appliance with one or several heat sources, wherein the electrical appliance has an electrical power supply unit with at least one heat source, said cooling assembly comprising
a fan device for cooling the at least one heat source of the power supply unit by means of a stream of air; and
a liquid cooling device;
wherein the fan device is arranged such that a radiator of the liquid cooling device is adapted to be acted upon at least partially by a stream of air from the fan device.

2. Cooling assembly as defined in claim 1, wherein the fan device and the radiator are arranged with respect to the power supply unit such that the at least one heat source of the power supply unit and the radiator are adapted to be cooled via the fan device.

3. Cooling assembly as defined in claim 1, wherein the power supply unit is designed to be fan-free.

4. Cooling assembly as defined in claim 1, wherein the fan device is arranged in a space next to the power supply unit.

5. Cooling assembly as defined in claim 1, wherein the radiator is arranged in a space next to the power supply unit.

6. Cooling assembly as defined in claim 1, wherein the power supply unit and the fan device are arranged on a common support.

7. Cooling assembly as defined in claim 1, wherein the power supply unit and the radiator are arranged on a common support.

8. Cooling assembly as defined in claim 1, wherein the fan device and the radiator are arranged on a common support.

9. Cooling assembly as defined in claim 1, wherein a circulation pump of the liquid cooling device and the power supply unit are arranged on a common support.

10. Cooling assembly as defined in claim 1, wherein the radiator is integrated into the power supply unit.

11. Cooling assembly as defined in claim 1, wherein a circulation pump is provided for the liquid cooling.

12. Cooling assembly as defined in claim 11, wherein the circulation pump is integrated into the power supply unit.

13. Cooling assembly as defined in claim 11, wherein the circulation pump is arranged on a housing of the power supply unit.

14. Cooling assembly as defined in claim 11, wherein the circulation pump is arranged outside a housing interior of a housing of the power supply unit.

15. Cooling assembly as defined in claim 11, wherein the circulation pump is connected to at least one thermal contact element.

16. Cooling assembly as defined in claim 11, wherein at least one thermal contact element is connected to the circulation pump via liquid lines in such a manner that a heat source is adapted to be contacted thermally by the at least one thermal contact element.

17. Cooling assembly as defined in claim 11, wherein in the flow guidance for cooling liquid the circulation pump is arranged upstream of the radiator with respect to a direction of flow for heated cooling liquid.

18. Cooling assembly as defined in claim 11, wherein the circulation pump is arranged at or in the vicinity of a feed-through of the power supply unit for a loom of cables.

19. Cooling assembly as defined in claim 11, wherein the circulation pump is arranged on a supporting plate located opposite an electrical connection of the power supply unit.

20. Cooling assembly as defined in claim 11, wherein an axis of rotation of the fan device is oriented transversely to an axis of rotation of the circulation pump.

21. Cooling assembly as defined in claim 1, wherein the radiator and the fan device are arranged one behind the other.

22. Cooling assembly as defined in claim 1, wherein the radiator is arranged beneath an electrical connection of the power supply unit.

23. Cooling assembly as defined in claim 11, wherein the circulation pump has an electric motor with a spherically mounted rotor.

24. Cooling assembly as defined in claim 23, wherein a blade wheel of the circulation pump is connected to the rotor.

25. Cooling assembly as defined in claim 1, wherein at least one compensation reservoir for cooling liquid is provided.

26. Cooling assembly as defined in claim 25, wherein the at least one compensation reservoir is arranged next to the power supply unit.

27. Cooling assembly as defined in claim 25, wherein the at least one compensation reservoir is arranged next to a circulation pump.

28. Cooling assembly as defined in claim 26, wherein the at least one compensation reservoir is integrated into a circulation pump.

29. Cooling assembly as defined in claim 1, having the radiator, a circulation pump, an expansion reservoir and the fan device.

30. Cooling assembly as defined in claim 29, comprising liquid conduits, at least one thermal contact element being arranged at said conduits.

31. Cooling assembly as defined in claim 1, wherein the liquid cooling device is prefilled with such an amount of cooling liquid that no subsequent filling is necessary during an expected service life.

32. Method for the liquid cooling of at least one heat source of an electrical appliance, comprising:
applying a stream of air from a fan device on a radiator;
wherein a stream of air from the fan device also acts on a power supply unit of the electrical appliance such that one or more heat sources of the power supply unit are cooled by means of the stream of air.
